(19) United States
(12) Patent Application Publication
(10) Pub. No.: US 2025/0260404 A1
(43) Pub. Date: Aug. 14, 2025

(54) LEVEL SHIFTER AND MEMORY DEVICE INCLUDING THE SAME

(71) Applicant: SAMSUNG ELECTRONICS CO., LTD., SUWON-SI (KR)

(72) Inventors: Sehyeok Oh, Suwon-si (KR); Chang Ki Kwon, Suwon-si (KR); Sungsik Kang, Suwon-si (KR); JI-YEON PARK, Suwon-si (KR); Gwangwon Lee, Suwon-si (KR); Ilho Jung, Suwon-si (KR)

(21) Appl. No.: 18/908,191

(22) Filed: Oct. 7, 2024

(30) Foreign Application Priority Data
Feb. 13, 2024 (KR) 10-2024-0020309

(51) Int. Cl. H03K 19/0185; G11C 5/14; H03K 3/356

(52) U.S. Cl. CPC H03K 19/018521; H03K 3/356113; H03K 3/356182; G11C 5/147

(57) ABSTRACT

A level shifter includes a Wilson current mirror circuit outputting an output voltage of an output node based on a first input voltage inverting a phase of an input voltage and a second input voltage inverting the phase of the first input voltage, a leakage current control circuit receiving the output voltage and controlling a leakage current generated in the Wilson current mirror circuit using the output voltage, and a latch circuit providing a voltage of a logic high level to the output node when the output voltage is a logic high level.

### CROSS-REFERENCE TO RELATED APPLICATION

This application claims priority to and the benefit of Korean Patent Application No. 10-2024-0020309 filed in the Korean Intellectual Property Office on Feb. 13, 2024, the entire contents of which are herein incorporated by reference.

### BACKGROUND

### (a) Technical Field

The disclosure relates to a level shifter, a memory device including the same, and an operation method of a level shifter.

### (b) Discussion of Related Art

As a level shifter circuit that shifts a voltage level of an input signal, a Wilson current mirror level shifter circuit may be used. The Wilson current mirror level shifter circuit may block a static current of a conventional current mirror level shifter circuit by using a transistor that feeds back the voltage at the output terminal. However, since the output terminal of the Wilson current mirror level shifter circuit is floating, it may output an unstable output voltage.

### SUMMARY

An embodiment relates to a level shifter that inhibits or prevents a leakage current and a memory device including the same.

An embodiment relates to a level shifter that inhibits or prevents a floating state of an output terminal, a memory device including the same, and a driving method of a level shifter.

An embodiment relates to a level shifter having improved transitions of an output voltage based on an input voltage and a memory device including the same.

A level shifter according to an embodiment may include a Wilson current mirror circuit outputting an output voltage of an output node based on a first input voltage inverting a phase of an input voltage and a second input voltage inverting the phase of the first input voltage, a leakage current control circuit receiving the output voltage and controlling a leakage current generated in the Wilson current mirror circuit using the output voltage, and a latch circuit providing a voltage of a logic high level to the output node when the output voltage is a logic high level.

A level shifter according to an embodiment may include a first transistor electrically connected to a ground voltage and including a gate to which a first input voltage is applied, wherein the first input voltage is an inverted copy of an input voltage, a second transistor electrically connected to the ground voltage and including a gate to which a second input voltage is applied, wherein the second input voltage is an inverted copy of the first input voltage, a third transistor electrically connected to the first transistor and including a gate to which an output voltage is applied, a fourth transistor electrically connected between the third transistor and a driving voltage source and including a gate connected to a mirror node, a fifth transistor electrically connected between an output node to which the output voltage is applied and the driving voltage source and including a gate connected to the mirror node, and at least one control transistor disposed between the mirror node and the driving voltage source and including a gate that receives the output voltage as a feedback.

A semiconductor device according to an embodiment may include a receiver that receives an input signal from an outside; and a level shifter receiving the input signal, outputting an output signal at an output node by level-shifting the input signal, and controlling a leakage current flowing to the output node and a voltage of the output node using the output signal.

### BRIEF DESCRIPTION OF THE DRAWINGS

FIG. 1 is a circuit diagram to explain a level shifter using a Wilson current mirror circuit according to an embodiment.

FIG. 2 is a block diagram to explain a level shifter according to an embodiment.

FIG. 3 is a block diagram to explain a current mirror circuit and an output circuit of a level shifter according to an embodiment.

FIG. 4 is a circuit diagram to explain a level shifter according to an embodiment.

FIG. 5 is a circuit diagram to explain a level shifter when applying an input voltage with a logic high level.

FIG. 6 is a circuit diagram to explain a level shifter when applying an input voltage with a logic low level.

FIG. 7 is a block diagram to explain a current mirror circuit and an output circuit of a level shifter according to another embodiment.

FIG. 8 is a circuit diagram to explain a level shifter according to another embodiment.

FIG. 9 is a waveform diagram to explain an input voltage and an output voltage of a level shifter.

FIG. 10 is a waveform diagram to explain an input voltage and an output voltage of a level shifter.

FIG. 11 is a drawing to explain a semiconductor device according to an embodiment.

### DETAILED DESCRIPTION

Embodiments of the present disclosure will be described more fully hereinafter with reference to the accompanying drawings. The present disclosure may be implemented in various different forms and is not limited to embodiments provided herein. Embodiments may be modified in various different ways, all without departing from the spirit or scope of the present disclosure.

The drawings and description are to be regarded as illustrative in nature and not restrictive. Like reference numerals designate like elements throughout the specification. In a flowchart described with reference to drawings in this specification, the order of operations may be changed, several operations may be merged, some operations may be divided, and specific operations may not be performed.

As used herein, the singular forms “a”, “an” and “the” are intended to include the plural forms as well, unless the context clearly indicates otherwise. Terms including ordinal numbers such as first, second, and the like may be used only to describe various components, and are not to be interpreted as limiting these components. These terms may be used for the purpose of distinguishing one constituent element from other constituent elements.

“Logic high level” and “logic low level” may be used to describe logic levels of signals. Signals with a “logic high level” may be distinguished from signals with a “logic low level”. According to an embodiment, the “logic high level” may be set to a voltage greater than the “logic low level”. For example, when a signal with a first voltage corresponds to a signal with a “logic high level,” a signal with a second voltage lower than the first voltage may correspond to a signal with a “logic low level.”

According to an embodiment, the logic level may be set to a different logic level or an opposite logic level. For example, a signal with a logic high level may be set to have a logic low level, and a signal with a logic low level may be set to have a logic high level.

Below, the present disclosure will be explained in more detail through one or more examples. These examples are merely intended to illustrate present disclosure, and the scope of the present disclosure is not limited by these examples.

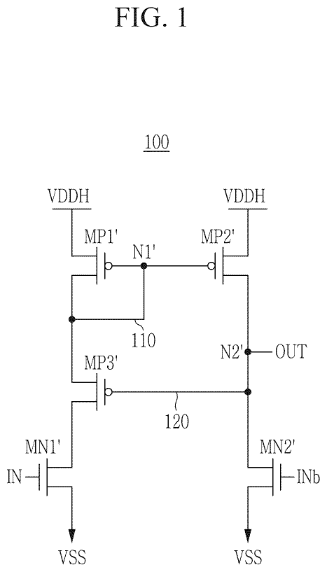

FIG. 1 is a circuit diagram to explain a level shifter using a Wilson current mirror circuit according to an embodiment.

Referring to FIG. 1, a Wilson current mirror circuit level shifter circuit 100 may include a matched transistor pair and a means for buffering a mirrored current output from said matched transistor pair. For example, the Wilson current mirror circuit level shifter circuit 100 may include a plurality of P-type transistors, and a plurality of N-type transistors. The plurality of N-type transistors may include a first mirror transistor MN1′ and a second mirror transistor MN2′. The plurality of P-type transistors may include a third mirror transistor MP1′, a fourth mirror transistor MP2′, and a fifth mirror transistor MP3′. Each source of the plurality of N-type transistors may be connected to a ground voltage VSS. Each source of the plurality of P-type transistors may be connected to a driving voltage VDDH.

The first mirror transistor MN1′ may be turned off or turn-on based on a first input voltage IN. If the first input voltage IN is a voltage of a logic low level, the first mirror transistor MN1′ may be turned off, and if the first input voltage IN is a voltage of a logic high level, the first mirror transistor MN1′ may be turned on. Based on the turn-off or turn-on state of the first mirror transistor MN1′, the operation of the third mirror transistor MP1′, the fourth mirror transistor MP2′, and the fifth mirror transistor MP3′ may be controlled. The third mirror transistor MP1′ and the fourth mirror transistor MP2′ may be the matched transistor pair of the Wilson current mirror circuit level shifter circuit 100.

The drain of the first mirror transistor MN1′ may be electrically connected to the drain of the fifth mirror transistor MP3′. The first input voltage IN may be applied to the gate of the first mirror transistor MN1′, and the source of the first mirror transistor MN1′ may be connected to the ground voltage VSS.

The second mirror transistor MN2′ may be in a turn-off state or a turn-on state based on the second input voltage INb, which may be an inversion of the first input voltage IN. If the second input voltage INb is the voltage of the logic low level, the second mirror transistor MN2′ may be turned off, and if the second input voltage INb is the voltage of the logic high level, the second mirror transistor MN2′ may be turned on. Based on the turn-off or turn-on state of the second mirror transistor MN2′, the operation of the third mirror transistor MP1′, the fourth mirror transistor MP2′, and the fifth mirror transistor MP3′ may be controlled.

The drain of the second mirror transistor MN2′ may be electrically connected to a gate of the fifth mirror transistor MP3′. For example, the drain of the second mirror transistor MN2′ may be electrically connected to the gate of the fifth mirror transistor MP3′ via a second connection 120. Additionally, the drain of the second mirror transistor MN2′ may be connected to the fourth mirror transistor MP2′ through the output node N2′. While the output node N2′ is illustrated as being disposed between the second connection 120 and the fourth mirror transistor MP2′, embodiments are not limited thereto, and the output node N2′ may be disposed between the second connection 120 and the second mirror transistor MN2′. The second input voltage INb may be applied to the gate of second mirror transistor MN2′. The source of the second mirror transistor MN2′ may be connected to the ground voltage VSS.

The third mirror transistor MP1′ and the fourth mirror transistor MP2′ may be electrically connected to each other, and may form a current mirror structure. The current to be copied may flow through the third mirror transistor MP1′, and the duplicated current may flow through the fourth mirror transistor MP2′.

The drain of the third mirror transistor MP1′ may be connected to the source of the fifth mirror transistor MP3′. For example, the Wilson current mirror circuit level shifter circuit 100 may include a negative feedback through the third mirror transistor MP1′ back to the gate of the fifth mirror transistor MP3′. The gate of the third mirror transistor MP1′ may be electrically connected to the fourth mirror transistor MP2′ through the first node N1′. The driving voltage VDDH may be applied to the source of the third mirror transistor MP1′.

The drain of the fourth mirror transistor MP2′ may be electrically connected to the second mirror transistor MN2′ through the output node N2′. Additionally, the drain of the fourth mirror transistor MP2′ may be connected to the gate of the fifth mirror transistor MP3′. For example, the drain of the fourth mirror transistor MP2′ may be connected to the gate of the fifth mirror transistor MP3′ through the output node N2′. The gate of the fourth mirror transistor MP2′ may be electrically connected to the third mirror transistor MP1′ through the first node N1′. The driving voltage VDDH may be applied to the source of fourth mirror transistor MP2′.

The fifth mirror transistor MP3′ may be formed to inhibit or prevent a leakage current flowing through the third mirror transistor MP1′ and the fourth mirror transistor MP2′. When the output voltage OUT applied to the output node N2′ is a logic high level, the fifth mirror transistor MP3′ may be turned off to inhibit or prevent leakage current occurring in the third mirror transistor MP1′ and the fourth mirror transistor MP2′.

The drain of the fifth mirror transistor MP3′ may be electrically connected to the source of the first mirror transistor MN1′. The gate of the fifth mirror transistor MP3′ may be electrically connected to the second mirror transistor MN2. Additionally, the gate of the fifth mirror transistor MP3′ may be electrically connected to the fourth mirror transistor MP2′. For example, the gate of the fifth mirror transistor MP3′ may be electrically connected to the fourth mirror transistor MP2′ through the output node N2′. The source of the fifth mirror transistor MP3′ may be electrically connected to the drain of the third mirror transistor MP1.

An operation of the Wilson current mirror circuit level shifter circuit depicted in FIG. 1 will be described herein.

A logic high level input voltage IN may be applied to the gate of the first mirror transistor MN1′, and a logic low level input voltage INb may be applied to the gate of the second mirror transistor MN2′. When the input voltage IN of a logic high level is applied to the gate of first mirror transistor MN1′, the first mirror transistor MN1′ may be turned on, and when the input voltage INb of a logic low level is applied to the gate of second mirror transistor MN2′, the second mirror transistor MN2′ may be turned off.

When the first mirror transistor MN1′ is turned on, the ground voltage VSS may be transmitted to the first node N1′ through the fifth mirror transistor MP3′ in the turn-on state. The ground voltage VSS may be transmitted to the first node N1′ may turn on the third mirror transistor MP1. When the third mirror transistor MP1′ is turned on, a current may flow to the first mirror transistor MN1′ through the third mirror transistor MP1 and the fifth mirror transistor MP3′ that are turned on from the driving voltage VDDH. Also, the ground voltage VSS may be transmitted to the first node N1′ may turn on the fourth mirror transistor MP2′.

When the fourth mirror transistor MP2′ is turned on, the output voltage OUT applied to the output node N2′ may have the voltage of the logic high level close to the driving voltage VDDH. If the output voltage OUT applied to the output node N2′ has the voltage of the logic high level, the fifth mirror transistor MP3′ may be turned off. When the fifth mirror transistor MP3′ is turned off, a current may not flow from the driving voltage VDDH to the fifth mirror transistor MP3′, so the third mirror transistor MP1′ and the fourth mirror transistor MP2′ may also be turned off.

When the second mirror transistor MN2′, the fourth mirror transistor MP2′, and the fifth mirror transistor MP3′ are turned off, the output node N2′ may be floating, not explicitly connected to a voltage source or a ground. Therefore, when a logic high level input voltage IN is applied to the gate of the first mirror transistor MN1′, the output voltage OUT applied to the output node N2′ may have an unpredictable voltage.

A leakage current may flow from the second mirror transistor MN2′ and the fourth mirror transistor MP2′ connected to the floating output node N2′. The leakage current generated in the second mirror transistor MN2′ in the turned off state may lower the output voltage OUT. The leakage current generated in the fourth mirror transistor MP2′ in the turned off state may increase the output node voltage OUT. Therefore, unpredictable voltages may be generated in the floating output node N2′.

A logic low level input voltage IN may be applied to the gate of the first mirror transistor MN1′, and a logic high level input voltage INb may be applied to the gate of the second mirror transistor MN2′. When the input voltage IN of the logic low level is applied to the gate of first mirror transistor MN1′, the first mirror transistor MN1′ may be turned off, and when the input voltage INb of the logic high level is applied to the gate of second mirror transistor MN2, the second mirror transistor MN2′ may be turned off.

When the second mirror transistor MN2′ is turned on, the output voltage OUT applied to the output node N2′ may be the voltage of the logic low level. The gate of the fifth mirror transistor MP3′ may be turned on by receiving a logic low level on the second connection 120. However, even if the fifth mirror transistor MP3′ is turned on, the first mirror transistor MN1′ is turned off, and the first node N1′ may be floating. Accordingly, the leakage current may flow by the fourth mirror transistor MP2′ connected to the floating first node N1′, and the output voltage OUT applied to the output node N2′ may change.

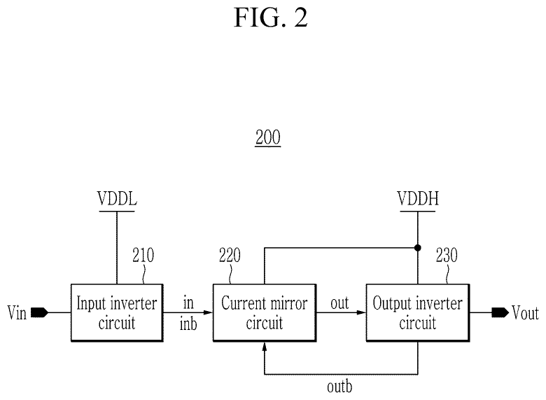

According to an embodiment, the floating state of the output node N2′ and the leakage current generated from fourth mirror transistor MP2 may be removed using a level shifter circuit. A level shifter circuit according to an embodiment the present disclosure is explained with reference to FIG. 2 to FIG. 11.

FIG. 2 is a block diagram illustrating a level shifter according to an embodiment.

Referring to FIG. 2, a level shifter 200 may include an input inverter circuit 210, a current mirror circuit 220, and an output inverter circuit 230.

The input inverter circuit 210 may receive an input voltage Vin. The input inverter circuit 210 may output a first input voltage INb and a second input voltage IN. The first input voltage INb and the second input voltage IN may be based on the input voltage Vin. The first input voltage INb may have a phase that is the inverted phase of the input voltage Vin, and a magnitude thereof may be the same as or similar to that of the input voltage Vin. Similarly, the second input voltage IN may have a phase that is the inverted phase of the first input voltage INb, and the magnitude thereof may be the same as or similar to that of the first input voltage INb. To generate the first input voltage INb and the second input voltage IN, the phase(s) of the first input voltage INb and/or the second input voltage IN may be changed relative to each other. For example, the phase of the first input voltage INb may be sped up or slowed down by 180 degrees. Meanwhile, the input inverter circuit 210 may receive an inverter driving voltage VDDL.

The current mirror circuit 220 may receive the first input voltage INb and the second input voltage IN from the input inverter circuit 210. The current mirror circuit 220 may output an output voltage OUT based on the first input voltage INb and second input voltage IN. For example, the current mirror circuit 220 may output a logic high level output voltage OUT based on the logic high level first input voltage INb and the logic low level second input voltage IN. Additionally, the current mirror circuit 220 may output a logic low level output voltage OUT based on the logic low level first input voltage INb and the logic high level second input voltage IN. Meanwhile, the current mirror circuit 220 may receive the driving voltage VDDH.

The current mirror circuit 220 may feedback a first output voltage OUTb received from the output inverter circuit 230. The current mirror circuit 220 may inhibit or prevent a floating state of the output voltage OUT node based on the first output voltage OUTb when the output voltage OUT is at a logic low level. The current mirror circuit 220 may control a leakage current that increases the output voltage OUT when the output voltage OUT is at a logic low level. The current mirror circuit 220 may inhibit or prevent the floating state of the output voltage OUT node based on the second input voltage IN when the output voltage OUT is at a logic high level. A detailed description of the current mirror circuit 220 will be provided herein.

The output inverter circuit 230 may output the first output voltage OUTb and a second input voltage Vout. The output inverter circuit 230 may output the first output voltage OUTb and the second input voltage Vout based on the output voltage OUT. The first output voltage OUTb may have a phase that is the inverted phase of the output voltage OUT, and the magnitude thereof may be the same as or similar to the output voltage OUT. The second output voltage Vout may have a phase that is the inverted phase of the first output voltage OUTb, and the magnitude thereof may be the same as or similar to the first output voltage OUTb. In the output of the first output voltage OUTb and the second output voltage Vout, the phase of first output voltage OUTb may speed up or slow down the phase by 180 degrees. Meanwhile, the output inverter circuit 230 may receive the driving voltage VDDH.

The output inverter circuit 230 may output the second output voltage Vout to the outside of the level shifter 200 based on the output voltage OUT. The second output voltage Vout may be different from the logic level range of the input voltage Vin. For example, the logic level range of the input voltage Vin may be about 0.3V to less than about 0.4V, and the logic level range of the second output voltage Vout may be about 0.9 to about 1.2V.

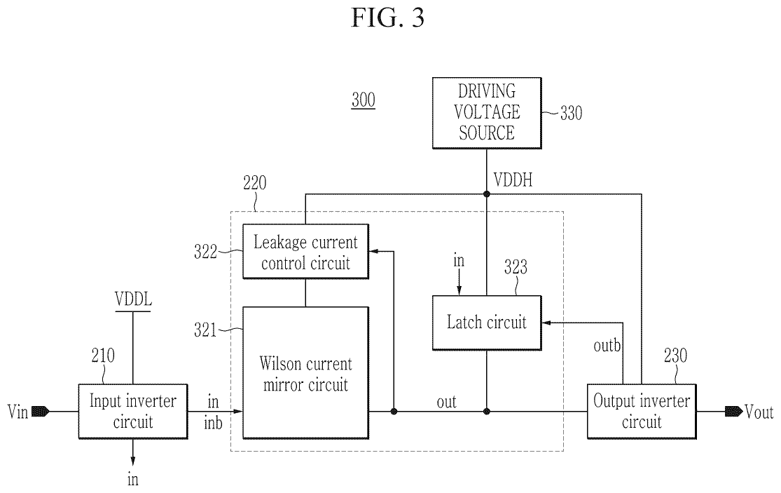

FIG. 3 is a block diagram illustrating a current mirror circuit and an output circuit of a level shifter according to an embodiment.

Referring to FIG. 2 and FIG. 3, the current mirror circuit 220 may include a Wilson current mirror circuit 321, a leakage current control circuit 322, and a latch circuit 323.

The Wilson current mirror circuit 321 may output an output voltage OUT having a logic level. The output voltage OUT may include the output voltage OUT of a logic low level or the output voltage OUT of a logic high level. When the Wilson current mirror circuit 321 outputs the output voltage OUT based on the ground voltage without copying a current, the output voltage OUT may have a logic low level. When the Wilson current mirror circuit 321 copies a current and outputs the output voltage OUT based on the copied current, the output voltage OUT may have a logic high level.

The leakage current control circuit 322 may control the leakage current flowing in the Wilson current mirror circuit 321. In some embodiments, the leakage current control circuit 322 may apply a predetermined voltage to a node of a floating stage included in the Wilson current mirror circuit 321. The leakage current control circuit 322 may control the leakage current flowing in the Wilson current mirror circuit 321 when the Wilson current mirror circuit 321 outputs the output voltage OUT of the logic low level. In some embodiments, the leakage current control circuit 322 may apply a voltage lower than the driving voltage VDDH to the node of the floating stage in the floating state. When the Wilson current mirror circuit 321 outputs the output voltage OUT of a logic high level, the voltage of less than the driving voltage VDDH may be applied to the node of the floating stage in the floating state. When the second input voltage IN applied to the Wilson current mirror circuit 321 transitions from the logic high level to the logic low level, the current needed for the output voltage OUT to the transition to the logic high level may flow through a transistor connected to the node to which the voltage less than the driving voltage VDDH may be applied by the leakage current control circuit 322.

In some embodiments, the leakage current control circuit 322 may include at least one P-type transistor. At least one P-type transistor may be coupled in series between a driving voltage source 330 and the Wilson current mirror circuit 321. Each gate of at least one P-type transistor included in the leakage current control circuit 322 may receive the feedback of the output voltage OUT output from the Wilson current mirror circuit 321. When the output voltage OUT is fed back to each gate of at least one P-type transistor, the operation of the leakage current control circuit 322 may be determined based on the logic level of the output voltage OUT. A detailed description of the leakage current control circuit 322 will be provided herein.

The latch circuit 323 may keep the logic level of the output voltage OUT substantially stable based on the second input voltage IN and first output voltage OUTb. The latch circuit 323 may operate when the Wilson current mirror circuit 321 outputs the output voltage OUT at the logic high level, and may maintain the output voltage OUT of the logic high level. The latch circuit 323 may not operate when the Wilson current mirror circuit 321 outputs the output voltage OUT of a logic low level.

In some embodiments, the latch circuit 323 may include two latch transistors. Two latch transistors may be electrically connected between the output node and the driving voltage source 330, and may include a gate connected to the mirror node. The second input voltage IN and the first output voltage OUTb may be input to the gates of two latch transistors, respectively.

In some embodiments, each of two latch transistors may include at least one P-type transistor. The second input voltage IN and the first output voltage OUTb may be input to the gate of at least one P-type transistor, respectively.

A detailed description of the latch circuit 323 will be provided herein.

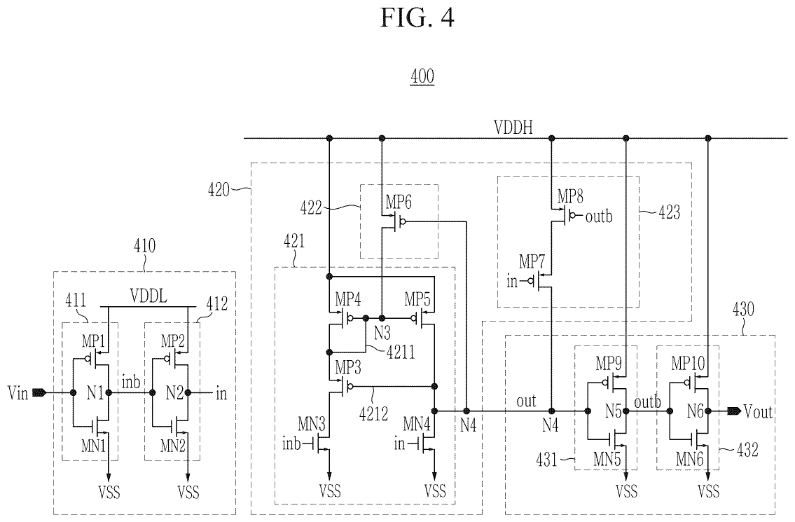

FIG. 4 is a circuit diagram to explain a level shifter according to an embodiment.

Referring to FIG. 4, a level shifter 400 may include an input inverter circuit 410, a current mirror circuit 420, and an output inverter circuit 430. The current mirror circuit 420 may include a Wilson current mirror circuit 421, a leakage current control circuit 422, and a latch circuit 423.

The input inverter circuit 410 may use a first input inverter 411 and a second input inverter 412. The input inverter circuit 410 may use a first input inverter 411 and a second input inverter 412 to generate a first input voltage INb, which is an inverted copy of an input voltage Vin, and a second input voltage IN, which is an inverted copy of the first input voltage INb. Through the first input inverter 411, the first input voltage INb may be generated by attenuating and stabilizing a fluctuation of the input power Vin. Through the second input inverter 412, the second input voltage IN may be generated by inverting the first input voltage INb.

The input inverter circuit 410 may include the first input inverter 411 and the second input inverter 412. The first input inverter 411 may receive the input voltage Vin and generate the first input voltage INb. The second input inverter 412 may receive the first input voltage INb and generate the second input voltage IN. The input inverter circuit 410 may apply the first input voltage INb and the second input voltage IN to the current mirror circuit 420.

The first input inverter 411 may include a first P-type transistor MP1 and a first N-type transistor MN1, and the second input inverter 412 may include a second P-type transistor MP2 and a second N-type transistor MN2. The first input inverter 411 and the second input inverter 412 may be electrically connected to each other through the first input node N1. That is, the output terminal of the first input inverter 411 may be electrically connected to the input terminal of the second input inverter 412 through the first input node N1.

The first P-type transistor MP1 and the first N-type transistor MN1 may be coupled in series between the inverter driving voltage VDDL and the ground voltage VSS. For example, the inverter driving voltage VDDL may be applied to a source of the first P-type transistor MP1, and the input voltage Vin may be applied to a gate of the first P-type transistor MP1. The first P-type transistor MP1 may be electrically connected to the first N-type transistor MN1 through the first input node N1. The ground voltage VSS may be applied to a source of the first N-type transistor MN1, and the input voltage Vin may be applied to a gate of the first N-type transistor MN1. The first N-type transistor MN1 may be electrically connected to the first P-type transistor MP1 through the first input node N1.

The second P-type transistor MP2 and the second N-type transistor MN2 may be coupled in series between the inverter driving voltage VDDL and ground voltage VSS. For example, the inverter driving voltage VDDL may be applied to a source of the second P-type transistor MP2, and the first input voltage INb may be applied to a gate of the second P-type transistor MP2. The second P-type transistor MP2 may be electrically connected to the second N-type transistor MN2 through the second input node N2. The ground voltage VSS may be applied to a source of the second N-type transistor MN2, and the first input voltage INb may be applied to a gate of the second N-type transistor MN2. The second N-type transistor MN2 may be electrically connected to the second P-type transistor MP2 through the second input node N2.

The Wilson current mirror circuit 421 may copy a current by using mirror-structured transistors included in the circuit. The mirror-structured transistor may include the fourth P-type transistor MP4 and the fifth P-type transistor MP5. The gates of each of the fourth P-type transistor MP4 and the fifth P-type transistor MP5 may be electrically connected to each other. The mirror-structured transistors may share a gate voltage with each other, and a current with the same amount of current as the amount of current flowing in the fourth P-type transistor MP4, which is the copy target, may flow in the fifth P-type transistor MP5. As another example, the amount of current flowing the in the fourth P-type transistor MP4, which is the copy target, multiplied by a predetermined gain value may flow in the fifth P-type transistor MP5.

In some embodiments, the Wilson current mirror circuit 421 may include a third N-type transistor MN3, a fourth N-type transistor MN4, a third P-type transistor MP3, a fourth P-type transistor MP4, and a fifth P-type transistor MP5.

The third N-type transistor MN3 and the fourth N-type transistor MN4 may receive the first input voltage INb and the second input voltage IN generated from the input inverter circuit 410. Based on this, the third N-type transistor MN3 and the fourth N-type transistor MN4 may be turned off or turned on independently, respectively. The third N-type transistor MN3 and the fourth N-type transistor MN4 may affect the operation of the third P-type transistor MP3, the fourth P-type transistor MP4, and the fifth P-type transistor MP5.

The drain of the third N-type transistor MN3 may be electrically connected to the drain of the third P-type transistor MP3. The first input voltage INb may be applied to the gate of the third N-type transistor MN3. The ground voltage VSS may be applied to the source of the third N-type transistor MN3.

The drain of the fourth N-type transistor MN4 may be electrically connected to the drain of the fifth P-type transistor MP5. Additionally, the drain of the fourth N-type transistor MN4 may be electrically connected to the third P-type transistor MP3 through a second signal line 4212. The second input voltage IN may be applied to the gate of the fourth N-type transistor MN4. The ground voltage VSS may be applied to the source of the fourth N-type transistor MN4.

The drain of the third P-type transistor MP3 may be electrically connected to the source of the third N-type transistor MN3. The output voltage OUT may be applied to the gate of the third P-type transistor MP3 through the second signal line 4212. The source of the third P-type transistor MP3 may be electrically connected to the drain of the fourth P-type transistor MP4.

The drain of the fourth P-type transistor MP4 may be electrically connected to the source of the third P-type transistor MP3. The fourth P-type transistor MP4 may be electrically connected to the fifth P-type transistor MP5 through a mirror node N3. The gate of the fourth P-type transistor MP4 may be electrically connected to the source of the third P-type transistor MP3 through a first signal line 4211. The driving voltage VDDH may be applied to the source of the fourth P-type transistor MP4.

The drain of the fifth P-type transistor MP5 may be electrically connected to the third P-type transistor MP3 and the fourth N-type transistor MN4 through an output node N4. The fifth P-type transistor MP5 may be electrically connected to the fourth P-type transistor MP4 through the mirror node N3. The gate of the fifth P-type transistor MP5 may be electrically connected to the source of the third P-type transistor MP3 through the first signal line 4211. The driving voltage VDDH may be applied to the source of the fifth P-type transistor MP5.

In view of the foregoing and referring to FIG. 1 and FIG. 4, the transistors of the Wilson current mirror circuit 421 may be mirror transistors. For example, the third N-type transistor MN3 of FIG. 4 may correspond to the first mirror transistor MN1′ of FIG. 1. Similarly, the fourth N-type transistor MN4 may correspond to the second mirror transistor MN2′, the fourth P-type transistor MP4 may correspond to the third mirror transistor MP1′, the fifth P-type transistor MP5 may correspond to the fourth mirror transistor MP2′, and the third P-type transistor MP3 may correspond to the fifth mirror transistor MP3′ (see also FIG. 1).

An example operation of the Wilson current mirror circuit 421 will be described herein.

The fourth P-type transistor MP4 and the fifth P-type transistor MP5 share a gate voltage and receive the same driving voltage VDDH, and the current flowing through the fourth P-type transistor MP4 may be copied. The third P-type transistor MP3, the fourth P-type transistor MP4, and the fifth P-type transistor MP5 may be operated differently based on the turn-on or turn-off states of the third N-type transistor MN3 and the fourth N-type transistor MN4, respectively.

The leakage current control circuit 422 may control the fourth P-type transistor MP4 and the fifth P-type transistor MP5. When the output voltage OUT is a logic low level, the leakage current control circuit 422 may turn off the fourth P-type transistor MP4 and the fifth P-type transistor MP5, and inhibit or prevent the leakage current flowing from the fourth P-type transistor MP4 and the fifth P-type transistor MP5.

The leakage current control circuit 422 may include a sixth P-type transistor MP6. The sixth P-type transistor MP6 may include a P-type transistor or a plurality of P-type transistors coupled in series. The plurality of P-type transistors may be coupled in series between the driving voltage VDDH and mirror node N3. The gate of plurality of P-type transistor may be connected to the output node N4. With the output voltage OUT is fed back to the gate of the sixth P-type transistor MP6, the operation of the sixth P-type transistor MP6 may be determined based on the logic level of the output voltage OUT.

An example operation of the leakage current control circuit 422 is described herein.

When the output voltage OUT is a logic low level, the sixth P-type transistor MP6 may apply the driving voltage VDDH to the mirror node N3 to turn off the fourth P-type transistor MP4 and the fifth P-type transistor MP5. When the fourth P-type transistor MP4 and the fifth P-type transistor MP5 are turned off, the leakage current flowing through the fourth P-type transistor MP4 and the fifth P-type transistor MP5 may be inhibited or prevented.

The latch circuit 423 may electrically connect the driving voltage source (not shown) and the output node N4. If the output voltage OUT applied to output node N4 is a logic high level, the driving voltage VDDH may be applied to the output node N4 from the driving voltage source (not shown) through the latch circuit 423. When the driving voltage VDDH is applied to the output node N4, which has the voltage of the logic high level, the output voltage OUT output from the output node N4 may maintain the logic high level voltage.

The latch circuit 423 may include a seventh P-type transistor MP7 and an eighth PMOS transistor MP8. Among the seventh P-type transistor MP7 and the eighth PMOS transistor MP8, the drain terminal of the seventh P-type transistor MP7, which is relatively close to output node N4, may be electrically connected to the output node N4. The gate terminal of the seventh PMOS transistor MP7 may receive the second input voltage IN from the input inverter circuit 410. The source terminal of the seventh PMOS transistor MP7 may be electrically connected to the drain terminal of the eighth PMOS transistor MP8.

The source terminal of the eighth PMOS transistor MP8 may receive the driving voltage VDDH from the driving voltage source (not shown). The gate terminal of the eighth PMOS transistor MP8 may receive feedback of the first output voltage OUTb from the output inverter circuit 430.

When the second input voltage IN and the first output voltage OUTb are the logic low level, the P-type transistor MP7 and the eighth PMOS transistor MP8 may be turned on and the driving voltage may be applied to the output node N4. However, if any one of the second input voltage IN or the first output voltage OUTb has a logic high level, the driving voltage may not be applied to the output node N4.

The output inverter circuit 430 may include a first output inverter 431 and a second output inverter 432 to generate the first output voltage OUTb, which is an inverted output voltage OUT, and the second output voltage Vout, which is an inverted first output voltage OUTb. The first output voltage OUTb may be generated by attenuating and stabilizing fluctuations in the output voltage OUT through the first output inverter 431. Through the second output inverter 432, the second output voltage Vout may be generated by inverting the first output voltage OUTb.

The output inverter circuit 430 may include the first output inverter 431 and the second output inverter 432. The first output inverter 431 may receive the output voltage OUT and generate the first output voltage OUTb. The second output inverter 432 may receive the first output voltage OUTb and generate the second output voltage Vout. The output inverter circuit 430 may apply the generated first output voltage OUTb to the latch circuit 423.

The first output inverter 431 may include a ninth P-type transistor MP1 and a fifth N-type transistor MN5. The second output inverter 432 may include a tenth P-type transistor MP10 and a sixth N-type transistor MN6. The first output inverter 431 and the second output inverter 432 may be electrically connected to each other through the first output node N5. That is, the output terminal of the first output inverter 431 may be electrically connected to the input terminal of the second output inverter 432 at the first output node N5.

The ninth P-type transistor MP9 and the fifth N-type transistor MN5 can be coupled in series between the driving voltage VDDH and the ground voltage VSS. For example, the driving voltage VDDH may be applied to the source of the ninth P-type transistor MP9, and the output voltage OUT may be applied to the gate of the ninth P-type transistor MP9. The ninth P-type transistor MP9 may be electrically connected to the fifth N-type transistor MN5 through the first output node N5.

The ground voltage VSS may be applied to the source of the fifth N-type transistor MN5, and the output voltage OUT may be applied to the gate of the fifth N-type transistor MN5. The fifth N-type transistor MN5 may be electrically connected to the ninth P-type transistor MP9 through the first output node N5.

The tenth P-type transistor MP10 and the sixth N-type transistor MN6 may be coupled in series between the driving voltage VDDH and the ground voltage VSS. For example, the driving voltage VDDH may be applied to the source of the tenth P-type transistor MP10, and the first output voltage OUTb may be applied to the gate of the tenth P-type transistor MP10. The tenth P-type transistor MP10 may be electrically connected to the sixth N-type transistor MN6 through the second output node N6. The ground voltage VSS may be applied to the source of the sixth N-type transistor MN6, and the first output voltage OUTb may be applied to the gate of the sixth N-type transistor MN6. The sixth N-type transistor MN6 may be electrically connected to the tenth P-type transistor MP10 through the second output node N6.

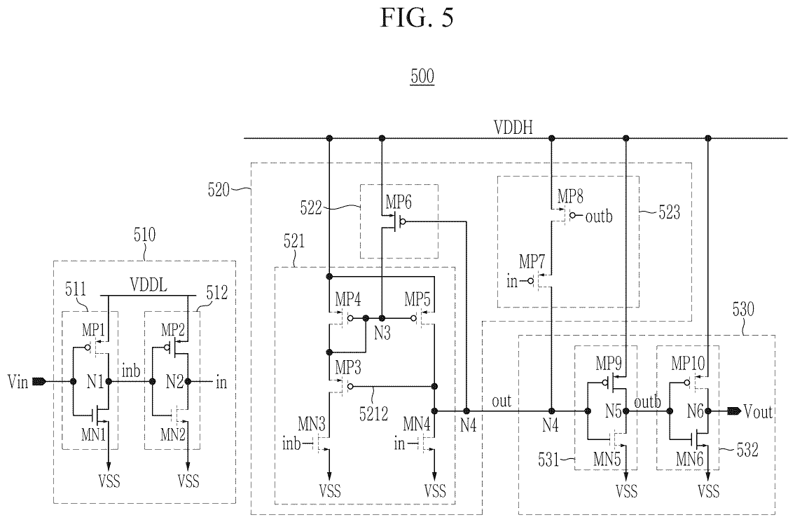

The level shifter 400 may include one or more circuits augmenting the Wilson current mirror circuit 421, and the level shifter 400 may output the second output voltage Vout, which reverses the phase of the input voltage Vin. If the first input voltage INb is applied to the gate of the third N-type transistor MN3, and the second input voltage IN is applied to the gate of the fourth N-type transistor MN4, the second output voltage Vout, which inverts the phase of the input voltage Vin, may be output. If the second input voltage IN is applied to the gate of the third N-type transistor MN3, and the first input voltage INb is applied to the gate of the fourth N-type transistor MN4, the second output voltage Vout, which has the same as the phase of the input voltage Vin, may be output. The phase inversion be a phase shift such that the phase of the second output voltage Vout is about 180 degrees different than the phase of the input voltage Vin. For example, the phase inversion may mean that the phase of the second output voltage Vout is 180 degrees faster or 180 degrees slower than the phase of the input voltage Vin. For better understanding and ease of description, FIG. 5 to FIG. 11 may illustrate example operations of the level shifter 400 of FIG. 4, including the Wilson current mirror circuit 421, configured to output the second output voltage Vout that inverts the phase of the input voltage Vin.

FIG. 5 is a circuit diagram to explain a level shifter when applying an input voltage with a logic high level.

Referring to FIG. 5, when the input voltage Vin with a logic high level is applied to the first input inverter 511 included in the input inverter circuit 510, the first P-type transistor MP1 is turned off, and the first N-type transistor MN1 is turned on, and the first input voltage INb may have a logic low level. When the first input voltage INb is applied to the second input inverter 512 included in the input inverter circuit 510, the second P-type transistor MP2 is turned on, and the second N-type transistor MN2 is turned off, and the second input voltage IN may have a logic high level.

When the first input voltage INb with a logic low level and the second input voltage IN with a logic high level are applied to the Wilson current mirror circuit 521 included in the current mirror circuit 520, the third N-type transistor MN3 may be turned off, and the fourth N-type transistor MN4 may be turned on.

Since the fourth N-type transistor MN4 is turned on, the output node N4 may have the voltage of the logic low level. The output voltage OUT of a logic low level is applied to the gate of the third P-type transistor MP3 through the second signal line 5212, and that the third P-type transistor MP3 may be turned on. The logic low level output voltage OUT is applied to the gate of the sixth P-type transistor MP6, and the sixth P-type transistor MP6 may be turned on. When the sixth P-type transistor MP6 is turned on, the driving voltage VDDH is applied to the mirror node N3, and the fourth P-type transistor MP4 and the fifth P-type transistor MP5 may be turned off.

Even if the voltage applied to the mirror node N3 does not have the voltage of the logic high level close to the voltage magnitude of the driving voltage VDDH, if the logic high level voltage is sufficient to turn off only the fourth P-type transistor MP4 and the fifth P-type transistor MP5, the leakage current generated from the turned off fifth P-type transistor MP5 may be inhibited or prevented.

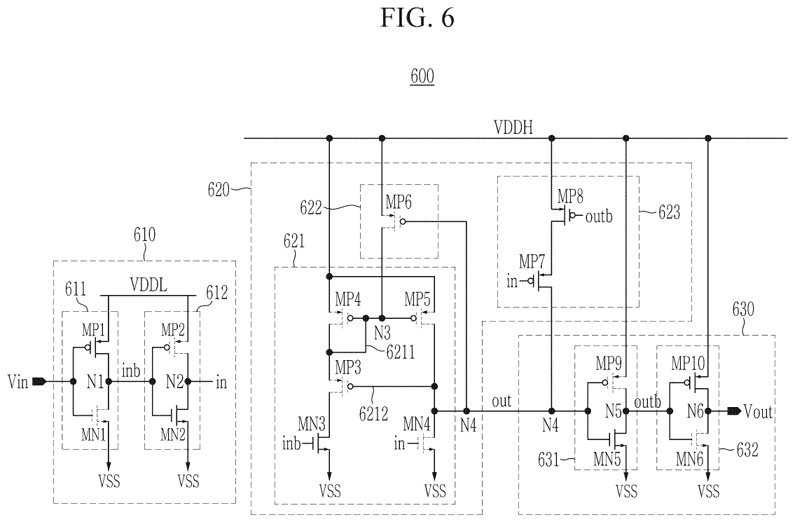

The sixth P-type transistor may include a P-type transistor or a plurality of P-type transistors coupled in series. The voltage of the logic high level lower than the driving voltage, which is obtained by subtracting a voltage drop across each of the transistors coupled in series from the driving voltage applied from the driving voltage source, may be applied to the mirror node N3. Details on this are explained with reference to FIG. 6.

The fifth P-type transistor MP5 connected between the output voltage OUT and the driving voltage VDDH is turned off, and a leakage current generated from the fifth P-type transistor MP5 may be inhibited or prevented. Accordingly, the output voltage OUT may be maintained at a logic low level.

When the output voltage OUT with logic low level is applied to the first output inverter 531 of the output inverter circuit 530, the ninth P-type transistor MP9 is turned on, and the fifth N-type transistor MN5 is turned off, and the first output voltage OUTb may have a voltage of the logic high level. When the first output voltage OUTb is applied to the second output inverter 532, the tenth P-type transistor MP10 is turned off, and the sixth N-type transistor MN6 is turned on, and the second output voltage Vout may have the voltage of the logic low level.

The first output voltage OUTb, which is the logic high level output from the first output inverter 531, may be applied to the gate of the eighth P-type transistor MP8, and the eighth P-type transistor MP8 may be turned off. The second input voltage IN, which is a logic high level output from the second input inverter 512, may be applied to the gate of the seventh P-type transistor MP7, and the seventh P-type transistor MP7 may be turned off. Therefore, when the input voltage Vin is at the logic high level, the latch circuit 523 may not provide the logic high level voltage to the output node N4 based on the second input voltage IN and the first output voltage OUTb at the logic high level.

In order for the output voltage OUT to be output at high speed based on the input voltage Vin applied to the input inverter circuit 510, after the fourth N-type transistor MN4 in the Wilson current mirror circuit 521 is turned on, the seventh P-type transistor MP7 or the eighth P-type transistor MP8 connected to the output node N4 must be quickly turned off. Since the second input voltage IN output from the input inverter circuit 510 may be applied directly to the gate of the seventh P-type transistor MP7, the output voltage OUT may be quickly output as a low logic level voltage.

The fifth P-type transistor MP5, the seventh P-type transistor MP7, and the eighth P-type transistor MP8 are turned off, and the fourth N-type transistor MN4 is turned on, so the output node N4 is not floating, and may stably have the voltage of the logic low level.

FIG. 6 is a circuit diagram to explain a level shifter when applying an input voltage with a logic low level.

FIG. 6 is the circuit diagram to explain the level shifter for the case that the input voltage of the logic low level is applied to the input inverter circuit after a steady state time has passed after applying the input voltage with a logic high level to the input inverter circuit in FIG. 5. FIG. 6 is described continuing from the contents of FIG. 5.

Referring to FIG. 6, when the input voltage Vin transitions from the voltage of the logic high level to the voltage of the logic low level, the input voltage Vin with logic low level may be applied to the first input inverter 611, and the first P-type transistor MP1 may be turned on. The first N-type transistor MN1 is turned off, and the first input voltage INb may have a logic high level. When the first input voltage INb is applied to the second input inverter 612 included in the input inverter circuit 610, the second P-type transistor MP2 is turned off, the second N-type transistor MN2 is turned on, and the second input voltage IN may have a logic low level.

When the first input voltage INb with logic high level and the second input voltage IN with logic low level are applied to the Wilson current mirror circuit 621 of the current mirror circuit 620, the third N-type transistor MN3 may be turned on, and the fourth N-type transistor MN4 may be turned off. The seventh P-type transistor MP7 may be turned on by receiving the second input voltage IN with a logic low level.

After the fourth N-type transistor MN4 is turned off, the eighth P-type transistor MP8 may not turn on immediately, and the output voltage OUT may maintain the logic low level. The gate of the third P-type transistor MP3 receives the logic low level output voltage OUT through the second signal line 6212, and the third P-type transistor may maintain the turn-on state. The gate of the sixth P-type transistor MP6 also receives the output voltage OUT of the logic low level, and the sixth P-type transistor MP6 may maintain the turn-on state.

In order for the output voltage OUT to quickly transition from the voltage of the logic low level to the voltage of the logic high level, the voltage applied to the mirror node N3 must quickly transition from the voltage of the logic high level to the voltage of the logic low level. In the present disclosure, in order for the voltage applied to mirror node N3 to quickly transition from the voltage of the logic high level to the voltage of the logic low level, the driving voltage source (not shown) must weaken the power of maintaining the voltage of the mirror node N3 with the logic high level through the sixth P-type transistor MP6.

Specifically, if the voltage magnitude of the logic high level applied to mirror node N3 is low, compared to the case where the magnitude of the logic high level voltage applied to mirror node N3 is large, the voltage applied to mirror node N3 may transition more quickly to the logic low level voltage. The current that lowers the voltage of the mirror node N3 is synced to the ground voltage VSS by the turned on third N-type transistor MN3 and the third P-type transistor MP3 maintaining the turn-on state, and the current that increases the voltage of the mirror node N3 may compete by the turned-on sixth P-type transistor MP6. In other words, when the input voltage Vin transitions from the voltage of the logic high level to the voltage of the logic low level, the leakage current control circuit 622 may transmit the driving voltage VDDH to the mirror node N3, and the Wilson current mirror circuit 621 may lower the voltage applied to the mirror node N3.

Although the voltage level of the mirror node N3 may be pulled down by the turned-on third N-type transistor MN3, the voltage level of the mirror node N3 may be not quickly pulled down by the turned-on sixth P-type transistor MP6.

Accordingly, the sixth P-type transistor MP6 may solve the above problem by including at least one P-type transistor coupled in series. At least one P-type transistor may be stacked to the Wilson current mirror circuit 621 direction from the driving voltage VDDH. Among at least one P-type transistor, the source of the P-type transistor closest to the driving voltage source (not shown) may receive the driving voltage VDDH from the driving voltage source (not shown). Among at least one P-type transistor, the drain of the P-type transistor closest to the Wilson current mirror circuit 621 may be electrically connected to the gate of the fourth P-type transistor MP4 and the gate of the fifth P-type transistor MP5 of the Wilson current mirror circuit 621. You can. Each gate of at least one P-type transistor may feedback the output voltage OUT output from the Wilson current mirror circuit 621.

When coupling P-type transistors in series, a length L may be a horizontal dimension length of a path from the source of a first one of the sixth P-type transistors MP6 to the drain of a last one of the sixth P-type transistors MP6 may become longer. With the addition of sixth P-type transistors MP6, the length L may become longer, and the driving voltage VDDH transmitted to the mirror node N3 may be lowered. For example, the driving voltage VDDH may be reduced by the voltage drop across each of the transistors connected in series. Therefore, the voltage applied to the mirror node N3 may have a voltage level lower than the driving voltage VDDH. If the voltage magnitude of the logic high level applied to the mirror node N3 is lowered, the voltage applied to mirror node N3 may transition more quickly from the logic high level to the logic low level.

Accordingly, the voltage applied to the mirror node N3 may decrease from a logic high level to a logic low level. When the mirror node N3 has the voltage of the logic low level, the fourth P-type transistor MP4 and the fifth P-type transistor MP5 may be turned on. When the fifth P-type transistor MP5 is turned on, the output voltage OUT may have a voltage of a logic high level.

When the output voltage OUT has the voltage of the logic high level, the third P-type transistor MP3 and the sixth P-type transistor MP6 may be turned off. When the third P-type transistor MP3 is turned off, a current may not flow through the third P-type transistor MP3, the mirror node N3 may have the voltage of the logic high level through the first signal line 6211, and the fourth P-type transistor MP4 and the fifth P-type transistor MP5 may be turned off.

When the output voltage OUT with a logic high level is applied to the first output inverter 631 of the output inverter circuit 630, the ninth P-type transistor MP9 may be turned off, the fifth N-type transistor MN5 may be turned on, and the first output voltage OUTb may have a logic low level. When the first output voltage OUTb is applied to the second output inverter 632, the tenth P-type transistor MP10 may be turned on, the sixth N-type transistor MN6 may be turned off, and the second output voltage Vout may have a logic high level.

When the voltage level of the input voltage Vin transitions from a logic high level to a logic low level, the first output voltage OUTb, which is a logic low level, may be applied to the gate of the eighth P-type transistor MP8, and the eighth P-type transistor MP8 may be turned on. Since the second input voltage IN, which is a logic low level, is applied to the gate of the seventh P-type transistor MP7 to be turned on, the output voltage OUT may have the voltage of the logic high level close to the driving voltage VDDH.

When the input voltage Vin has the voltage of the logic low level, the seventh P-type transistor MP7 and the eighth P-type transistor MP8 may receive the second input voltage IN and the first output voltage OUTb, and the output voltage OUT may maintain the voltage of the logic high level. In other words, when the voltage level of the input voltage Vin transitions from a logic high level to a logic low level, the latch circuit 623 may receive the second input voltage IN and the first output voltage OUTb of a logic low level and maintain the output voltage OUT as a logic high level.

The seventh P-type transistor MP7 and the eighth P-type transistor MP8 may each include at least one P-type transistor. The P-type transistors of the seventh P-type transistor MP7 and the eighth P-type transistor MP8 may be coupled in series to the output inverter circuit 630. A length L, which is a horizontal dimension length of a path from a drain of a first transistor of the seventh P-type transistor MP7 relatively close to output node N4 to a source of a last transistor of the eighth P-type transistor MP8 relatively far from output node N4 may also become longer.

With the addition of P-type transistors to the seventh P-type transistors MP7 and the eighth P-type transistors MP8, the length L may become longer, and the driving voltage VDDH applied to the source of the eighth P-type transistor MP8 may not be sufficiently transmitted to the drain of the eighth P-type transistor MP8. For example, the driving voltage VDDH may be reduced by the voltage drop across each of the transistors connected in series. Additionally, the logic high level voltage applied to the source of the seventh P-type transistor MP7 may not be sufficiently transmitted to the drain of the seventh P-type transistor MP7. Therefore, the voltage applied to the output node N4, which is electrically connected to the drain of the seventh P-type transistor MP7, may have a voltage of a logic high level that is smaller than the magnitude of the driving voltage VDDH. If the magnitude of the logic high level of the output voltage OUT is lowered, the output voltage OUT may quickly transition from the voltage of the logic high level to the voltage of the logic low level.

When the fourth N-type transistor MN4 and the fifth P-type transistor MP5 are turned off, a leakage current may occur from the fourth N-type transistor and the fifth P-type transistor and affect the output voltage OUT. When the seventh P-type transistor MN4 and the eighth P-type transistor MN8 are turned on and the output voltage OUT has the voltage of the logic high level close to the driving voltage VDDH, the influence of the leakage current on the output voltage OUT may be reduced or minimized. Therefore, the output node N4 may have a stable logic high level voltage without floating.

A voltage level output from the mirror node N3 and the output node N4, when the voltage level of the input voltage Vin transitions from a logic low level to a logic high level, is described with reference to FIG. 5 and FIG. 6.

If the input voltage Vin has a logic high level, the first input voltage INb may have a logic low level, and the second input voltage IN may have a logic low level.

When the second input voltage IN has a logic low level, the Wilson current mirror circuit 521 may lower the output voltage OUT into a logic low level. The second input voltage IN is applied to the fourth N-type transistor, and the ground voltage VSS may be applied to the output node N4. Accordingly, the output voltage OUT may transition from a logic high level to a logic low level.

If the output voltage OUT has the voltage of the logic low level, the leakage current control circuit 522 may increase the voltage applied to the mirror node N3. The third P-type transistor MP3 and the sixth P-type transistor MP6, to which the output voltage OUT of a logic low level is applied, may be turned on. Accordingly, the driving voltage VDDH is applied to the mirror node N3 through the sixth P-type transistor MP6, and that the mirror node N3 may have the voltage of the logic high level close to the driving voltage VDDH.

When the mirror node N3 has the voltage of the logic high level, the voltage of the logic high level may be applied to the gate of each of the fourth P-type transistor MP4 and the fifth P-type transistor MP5. MP5 and that the fourth P-type transistor MP4 and the fifth P-type transistor MP5 may be turned off.

When the voltage level of the input voltage Vin transitions from a logic low level to a logic high level, the latch circuit 523 may not provide the voltage of the logic high level to the output node N4 based on the second input voltage IN and the first output voltage OUTb of the logic high level. For example, if any one of the second input voltage IN or the first output voltage OUTb has a logic high level, the driving voltage may not be applied to the output node N4.

If the output voltage OUT has a logic low level, the first output voltage OUTb may have a logic high level, and the second output voltage Vout may have a logic low level. When the second input voltage and first output voltage with a logic high level are applied to the seventh P-type transistor MP7 and the eighth P-type transistor MP8, respectively, the seventh P-type transistor MP7 and the eighth P-type transistor MP8 may be turned off. When the seventh P-type transistor MP7 and the eighth P-type transistor MP8 are turned off, since the driving voltage VDDH may no longer be applied to the output node N4, the output voltage OUT may not maintain a logic high level. Therefore, the output node N4 may receive the ground voltage VSS only from the fourth N-type transistor MN4, and the output voltage OUT may have a stable logic low level voltage.

In order for the output voltage OUT to quickly transition from a logic low level to a logic high level based on the input voltage Vin, the number of the sixth P-type transistors MP6 may satisfy a first reference and a second reference.

The first reference may mean determining the number of the sixth P-type transistors MP6 so that the sixth P-type transistors MP6 increase the voltage applied to the mirror node N3 to a logic high level when the output voltage OUT is at a logic low level to have a level at which the fourth P-type transistor MP4 and the fifth P-type transistor MP5 may be turned off.

The second reference may mean determining the number of the sixth P-type transistors MP6, where even though the sixth P-type transistors MP6 increase the voltage applied to the mirror node N3 when the output voltage Vout transitions from logic low level to logic high level, the third N-type transistor MN3 may lower the voltage applied to the mirror node N3 to a logic low level so the fourth P-type transistor MP4 and the fifth P-type transistor MP5 may be temporarily turned on.

In order for the output voltage OUT to quickly transition from a logic high level to a logic low level based on the input voltage Vin, the number of the seventh P-type transistors MP7 and the number of the eighth P-type transistors MP8 may be determined to meet a first reference and a second reference.

The first reference may mean determining the number of the seventh P-type transistors MP7 and the eighth P-type transistors MP8 so that when the output voltage OUT is a logic high level, the seventh P-type transistors MP7 and the eighth P-type transistors MP8 maintain the output voltage OUT in a logic high level, and the third P-type transistor MP3 and the sixth P-type transistor MP6 may be turned off.

The second reference may mean determining the number of the seventh P-type transistors MP7 and the eighth P-type transistors MP8, even though the seventh P-type transistors MP7 and the eighth P-type transistors MP8 maintain the output voltage OUT at the logic high level when the output voltage Vout transitions from a logic high level to a logic low level, the fourth N-type transistor MN4 may lower the output voltage OUT to a logic low level and the third P-type transistor and the sixth P-type transistor MP6 may be turned on.

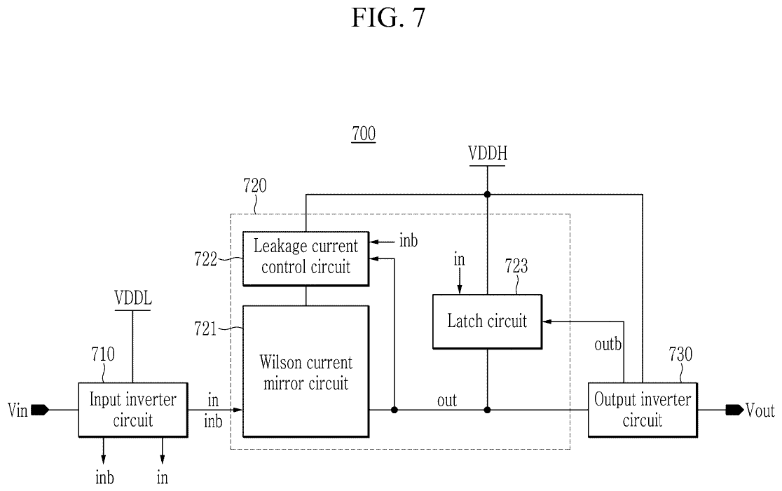

FIG. 7 is a block diagram to explain a current mirror circuit and an output circuit of a level shifter according to another embodiment.

FIG. 7 is similar to the block diagram for explaining the current mirror circuit and the output circuit of the level shifter in FIG. 3. In FIG. 7, the first input voltage INb may be applied to the leakage current control circuit 722 of the current mirror circuit 720.

The phases of the first input voltage INb and the output voltage OUT may be the same. Specifically, the first input voltage INb is to invert the phase of the input voltage Vin through the input inverter circuit 210, and the output voltage OUT output through the current mirror circuit 721 may also be output as the inverted phase of the input voltage Vin. Therefore, if the first input voltage INb has the voltage of a logic high level, the output voltage OUT may also have the voltage of a logic high level, and if the first input voltage INb has the voltage of a logic low level, the output voltage OUT may also have the voltage of a logic low level.

The voltage magnitudes of the first input voltage INb and the output voltage OUT may be different. The voltage magnitude of the first input voltage INb may be determined based on the input inverter circuit 210, and the voltage magnitude of the output voltage OUT may be determined based on the current mirror circuit 721 of the level shifter 700. However, for better understanding and case of description, in the present disclosure, it may be assumed that the voltage magnitude of the output voltage OUT is equal to the magnitude of the first input voltage INb.

Accordingly, when the first input voltage INb is applied to the leakage current control circuit 722, the magnitude and phase of the voltage applied to the gate of the sixth P-type transistor MP6 may be equal to the magnitude and phase of the voltage applied to the gate of the sixth P-type transistor MP6 when the output voltage OUT is applied to the leakage current control circuit 722.

The first input voltage INb may be determined through the input inverter circuit 210, and the output voltage OUT may be determined later through the current mirror circuit 721. Therefore, when the first input voltage INb is applied to the leakage current control circuit 722, the driving speed of the leakage current control circuit 722 may be faster than when the output voltage OUT is applied to the leakage current control circuit 722.

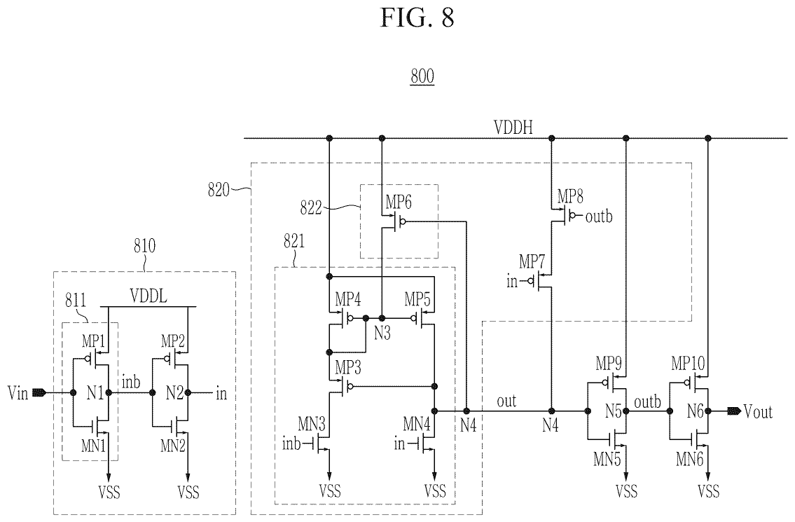

FIG. 8 is a circuit diagram to explain a level shifter according to another embodiment.

FIG. 8 is similar to the circuit diagram to explain the level shifter in FIG. 4. In FIG. 8, the first input voltage INb may be applied to the sixth P-type transistor MP6 included in the leakage current control circuit 822 of the current mirror circuit 820.

Referring to FIG. 8, the first input voltage INb output from the first input inverter 811 of the input inverter circuit 810 may be applied to the gate of the sixth P-type transistor MP6. The first input voltage INb may be determined through the first input inverter 811, and the output voltage OUT may be determined later through the current mirror circuit 821. Therefore, when the first input voltage INb is applied to the leakage current control circuit 822, the driving speed of the leakage current control circuit 822 may be faster than when the output voltage OUT is applied to the leakage current control circuit 822.

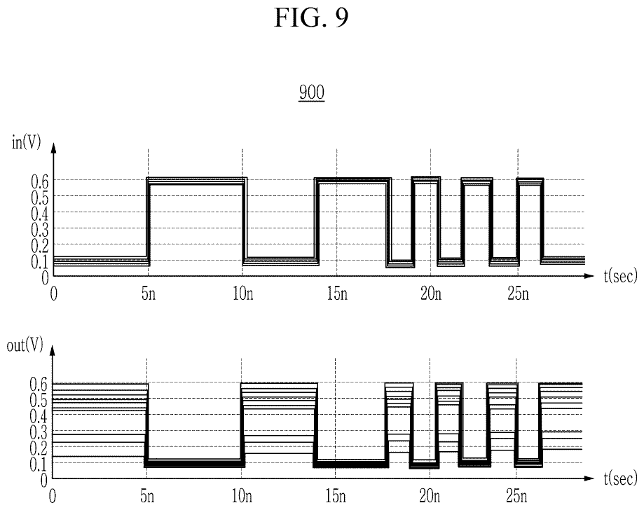

FIG. 9 is a waveform diagram to explain an input voltage and an output voltage of a level shifter.

FIG. 9 is the waveform diagram to explain the input voltage and the output voltage of the level shifter, which does not include the leakage current control circuit and the latch circuit in the present disclosure. Referring to FIG. 9, the second input voltage IN may have a value between about 0 V and about 0.6 V. The output voltage OUT may have a value between about 0V to about 0.6V. At this time, the logic low level voltage may mean about 0V, and the logic high level voltage may mean about 0.6V.

The time (t) for the second input voltage IN to apply the voltage of the logic low level to the Wilson current mirror circuit and the latch circuit may be different from the time (t) for the second input voltage IN to apply the voltage of the logic high level to the Wilson current mirror circuit and latch circuit. Likewise, the time (t) at which the logic low level voltage is output from the Wilson current mirror circuit and the time (t) at which the logic high level voltage is output from the Wilson current mirror circuit may be different.

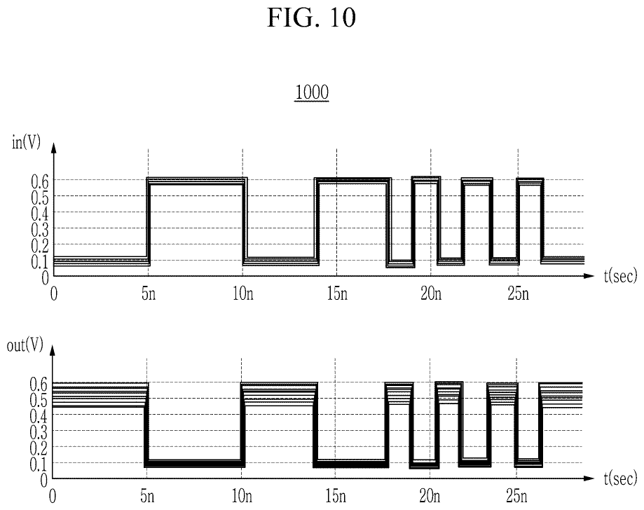

If the second input voltage IN has the voltage of the logic high level, the output voltage OUT may have the voltage of the logic low level. If the second input voltage IN has the voltage of the logic low level, the output voltage OUT may be unstable. For example, if the second input voltage IN has the voltage of the logic low level, the output voltage OUT may simultaneously have the voltage of the logic high level as well as the voltage of the logic low level. According to an embodiment, the leakage current control circuit and the latch circuit may be included in the level shifter, and a waveform diagram to explain input and output voltages of the level shifter including the leakage current control circuit and the latch circuit is described in FIG. 10.

FIG. 10 is a waveform diagram to explain an input voltage and an output voltage of a level shifter.

FIG. 10 is the waveform diagram to explain the second input voltage IN and output voltage OUT of the level shifter including the leakage current control circuit and latch circuit in the present disclosure. Referring to FIG. 9 and FIG. 10, the second input voltage IN may have a value between about 0V and about 0.6V. The output voltage OUT may have a value between about 0V and about 0.6V. If the second input voltage IN has the voltage of the logic high level, the output voltage OUT may have the voltage of the logic low level. If the second input voltage IN has the voltage of the logic low level, the output voltage OUT may have the voltage of the logic high level.

Compared to FIG. 9, if the second input voltage IN has the voltage of the logic low level in FIG. 10, the output voltage OUT may stably have the voltage of the logic high level. As described herein, since the seventh P-type transistor MP7 and the eighth P-type transistor MP8 included in the latch circuit are turned on, the output voltage OUT may stably maintain the voltage of the logic high level. In addition, the sixth P-type transistor MP6 included in the leakage current control circuit (422 in FIG. 4) turns off the fifth P-type transistor MP5 and reduces the leakage current generated from the fifth P-type transistor MP5, and the output voltage OUT may maintain the voltage of the logic high level more stably.

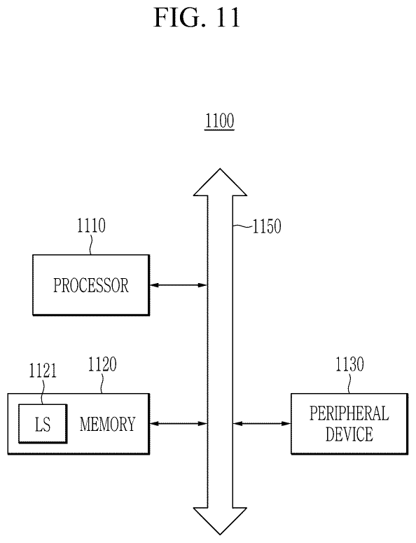

FIG. 11 is a view to explain a memory device according to an embodiment.

Referring to FIG. 11, a semiconductor device 1100 according to an embodiment may include a processor 1110, a memory 1120, and a peripheral device 1130 that are electrically connected to a system bus 1150.

The processor 1110 may control an input/output of a data from the memory 1120 and the peripheral device 1130, and may perform an image processing of an image data transmitted between devices.

The memory 1120 may include a volatile memory such as a dynamic random access memory (DRAM) and/or a non-volatile memory such as a flash memory. The memory 1120 may be a DRAM, a phase-change random access memory (PRAM), a magnetic random access memory (MRAM), a resistive random access memory (ReRAM), a ferroelectric random access memory (FRAM), a NOR flash memory, a NAND flash memory, or a fusion flash memory (for example, a memory that combines a static random access memory (SRAM) buffer, a NAND flash memory, and a NOR interface logic). The memory 1120 may store an image data obtained from the peripheral device 1130 or a video signal processed by the processor 1110.

LPDDR is an abbreviation for “Low Power Double Data Rate” and may include a type of a synchronous RAM typically used in low electric power mobile devices. The mobile devices may include portable phones, tablets, laptops, or cameras. The LPDDR may support a low electric power mode, and may improve a power-efficiency in the mobile devices. The LPDDR is also a memory commonly used in low electric power mobile devices, and may be included in the memory 1120.

The memory 1120 may include a receiver and level shifter 1121. The receiver may receive input signals from the outside. The level shifter 1121 may receive an input signal from the receiver and level-shift the received input signal. At the output node, the level-shifted input signal may be output as an output signal. The level shifter 1121 may control the leakage current flowing to the output node and the voltage of the output node based on the output signal.

The level shifter 1121 may include the Wilson current mirror circuit that generates the output signal based on the input signal described with reference to FIG. 2 to FIG. 8, the leakage current control circuit that turns off the transistor included in the current mirror circuit when the output signal is the logic low level to inhibit or prevent leakage current generated from the transistor, and the latch circuit applying the driving voltage to stably output the output signal when the output signal is the logic high level.

The peripheral device 1130 may be a device that converts a motion picture or a still image, such as a camera, a scanner, or a webcam, into an electrical signal. The image data acquired through the peripheral device 1130 may be stored in the memory 1120.

The semiconductor device 1100 may be installed in a mobile device such as a smart phone, but is not limited thereto, and may be installed in various types of electronic products that display images.

In some embodiments, each component or combinations of two or more components described with reference to FIG. 1 to FIG. 11 may be implemented as a digital circuit, a programmable or non-programmable logic device or array, an application specific integrated circuit (ASIC), or the like.

While this disclosure has been described in connection with what is presently considered to be practical embodiments, it is to be understood that the invention is not limited thereto, but, on the contrary, is intended to cover various modifications and equivalent arrangements included within the spirit and scope of the appended claims.

What is claimed is:

1. A level shifter comprising:
a Wilson current mirror circuit configured to output an output voltage of an output node based on a first input voltage inverting a phase of an input voltage and a second input voltage inverting the phase of the first input voltage;
a leakage current control circuit configured to receive the output voltage and control a leakage current generated in the Wilson current mirror circuit using the output voltage; and
a latch circuit configured to provide a voltage of a logic high level to the output node when the output voltage is a logic high level.

2. The level shifter of claim 1, further comprising:
an output inverter circuit configured to receive the output voltage and output a first output voltage inverting the phase of the output voltage and a second output voltage inverting the phase of the first output voltage,
wherein the Wilson current mirror circuit comprises:
a first mirror transistor electrically connected to a ground voltage and including a gate to which the second input voltage is applied;
a second mirror transistor electrically connected to the ground voltage and including a gate to which the first input voltage is applied;
a third mirror transistor electrically connected to the first mirror transistor and including a gate to which the output voltage is applied;
a fourth mirror transistor electrically connected between the third mirror transistor and a driving voltage source and including a gate connected to a mirror node; and
a fifth mirror transistor electrically connected between the output node and the driving voltage source and including a gate connected to the mirror node.

3. The level shifter of claim 2, wherein:
the latch circuit is further configured to receive the second input voltage and the first output voltage and provide a voltage of a logic high level to the output node based on the second input voltage and the first output voltage.

4. The level shifter of claim 3, wherein the latch circuit comprises:
a first latch transistor receiving the second input voltage; and
a second latch transistor receiving the first output voltage,
wherein the first latch transistor and the second latch transistor are coupled in series between the driving voltage source providing a driving voltage and the output node, and
the first latch transistor is turned on based on the second input voltage, and the second latch transistor is turned on based on the first output voltage so that the driving voltage is applied to the output node from the driving voltage source.

5. The level shifter of claim 4, wherein:
when a voltage level of the input voltage transitions from a logic high level to a logic low level,
the latch circuit is further configured to receive the second input voltage and the first output voltage of the logic low level and maintain the output voltage with the logic high level.

6. The level shifter of claim 3, wherein:
when a voltage level of the input voltage transitions from a logic low level to a logic high level,
the latch circuit is not further configured to provide the voltage of the logic high level to the output node based on the second input voltage or the first output voltage of the logic high level.

7. The level shifter of claim 2, wherein the leakage current control circuit comprising a control transistor including a gate configured to receive the output voltage is electrically connected between the driving voltage source that provides a driving voltage and the mirror node, and provides the driving voltage to the mirror node so that the fourth mirror transistor and the fifth mirror transistor are turned off when the output voltage is a logic low level.

8. The level shifter of claim 7, wherein the leakage current control circuit further comprises a plurality of control transistors, including the control transistor, each control transistor of the plurality of control transistors including a gate configured to receive the output voltage, and the plurality of control transistors are coupled in series between the driving voltage source and the mirror node.

9. The level shifter of claim 7, wherein the leakage current control circuit is configured to transmit the driving voltage to the mirror node when the output voltage is at a logic low level, causing the fourth mirror transistor and the fifth mirror transistor to be turned off, and
does not transmit the driving voltage to the mirror node when the output voltage is at a logic high level, causing the fourth mirror transistor and the fifth mirror transistor to be temporarily turned on.

10. The level shifter of claim 7, wherein when a voltage level of the input voltage transitions from a logic high level to a logic low level,
the leakage current control circuit is further configured to transmit the driving voltage to the mirror node, and the Wilson current mirror circuit is configured to lower a voltage of the mirror node.

11. The level shifter of claim 10, wherein when the voltage of the mirror node is lowered by the Wilson current mirror circuit, the fourth mirror transistor and the fifth mirror transistor are further configured to be turned on, and the output voltage is further configured to transit from a logic low level to a logic high level.

12. The level shifter of claim 9, wherein when a voltage level of the input voltage transitions from a logic low level to a logic high level,
the leakage current control circuit is further configured to increase a voltage of the mirror node, and the Wilson current mirror circuit is further configured to lower the output voltage to the logic low level.

13. The level shifter of claim 9, wherein the control transistor receiving the output voltage is further configured to be turned on, and the voltage applied to the mirror node increases, causing the fourth mirror transistor and the fifth mirror transistor to be turned off.

14. A level shifter comprising:
a first transistor electrically connected to a ground voltage and including a gate to which a first input voltage is applied, wherein the first input voltage is an inverted copy of an input voltage;
a second transistor electrically connected to the ground voltage and including a gate to which a second input voltage is applied, wherein the second input voltage is an inverted copy of the first input voltage;
a third transistor electrically connected to the first transistor and including a gate to which an output voltage is applied;
a fourth transistor electrically connected between the third transistor and a driving voltage source and including a gate connected to a mirror node;
a fifth transistor electrically connected between an output node to which the output voltage is applied and the driving voltage source and including a gate connected to the mirror node; and
at least one control transistor disposed between the mirror node and the driving voltage source and including a gate configured to receive the output voltage as a feedback.

15. The level shifter of claim 14, further comprising:
at least one first latch transistor configured to receive the second input voltage; and
at least one second latch transistor configured to receive a first output voltage that is an inverted copy of the output voltage,
wherein the at least one first latch transistor and the at least one second latch transistor are coupled in series.

16. The level shifter of claim 15, wherein:
when the voltage level of the input voltage transitions from a logic high level to a logic low level,
the first transistor is turned-on, the second transistor is turned off, the fourth transistor and the fifth transistor are turned-on, and the driving voltage is applied to the output node, and
the at least one first latch transistor and the at least one second latch transistor causing the output voltage to be maintained by the driving voltage.

17. The level shifter of claim 15, wherein:
when the voltage level of the input voltage transitions from a logic low level to a logic high level,
the second transistor is turned-on, the first transistor is turned off, the third transistor and the at least one control transistor are turned-on, and the ground voltage is configured to be applied to the output node,
the driving voltage is applied to the mirror node causing the fourth transistor and the fifth transistor to be turned off, and
the at least one first latch transistor and the at least one second latch transistor are turned off causing the output voltage to be maintained by the ground voltage.

18. The level shifter of claim 14, further comprising a leakage current control circuit comprising a plurality of control transistors, including the at least one control transistor, coupled in series,
wherein a number of the plurality of control transistors is provided configuring the leakage current control circuit,
wherein when the output voltage is at logic low level, the voltage applied to the mirror node is raised to a logic high level causing the fourth transistor and the fifth transistor to be turned off, and
when the output voltage transitions from a logic low level to a logic high level, the first transistor lowers the voltage applied to the mirror node to a logic low level causing the fourth transistor and the fifth transistor to be temporarily turned on.

19. The level shifter of claim 15, further comprising a latch circuit comprising the at least one first latch transistor and the at least one second latch transistor wherein:
a number of the at least one first latch transistor and the at least one second latch transistor is provided configuring the latch circuit,
wherein when the output voltage is a logic high level, the at least one first latch transistor and the at least one second latch transistor maintain the output voltage at the logic high level, and the third transistor and the at least one control transistor are turned off, and
when the output voltage transitions from a logic high level to a logic low level, the second transistor lowers the output voltage to a logic low level causing the third transistor and the at least one control transistor to be turned-on while the at least one first latch transistor and the at least one second latch transistor maintain the output voltage as the logic high level.

20. A semiconductor device comprising:
a receiver that receives an input signal from an outside; and
a level shifter configured to receive the input signal, output an output signal at an output node by level-shifting the input signal, and control a leakage current flowing to the output node and a voltage of the output node using the output signal.
